(19) United States
(12) Patent Application Publication
(10) Pub. No.: US 2026/0063703 A1
(43) Pub. Date: Mar. 5, 2026

(54) AUTOMATIC TEST METHOD, AUTOMATIC TEST DEVICE, AND STORAGE MEDIUM

(71) Applicants: Fu Tai Hua Industry (Shenzhen) Co., Ltd., Shenzhen (CN); HON HAI PRECISION INDUSTRY CO., LTD., New Taipei (TW)

(72) Inventor: JIANG-FENG SHAN, Zhengzhou (CN)

(21) Appl. No.: 19/019,878

(22) Filed: Jan. 14, 2025

(30) Foreign Application Priority Data
Aug. 29, 2024 (CN) 202411204782.0

(51) Int. Cl. G01R 31/28; G06T 7/73

(52) U.S. Cl. CPC G01R 31/2834; G06T 7/74

(57) ABSTRACT

The present disclosure provides an automatic test method, an automatic test device, and a storage medium. The automatic test method is applied to the automatic test device. The automatic test device includes a driving mechanism, a detection mechanism and a dual-probe mechanism. The automatic test method includes controlling the driving mechanism to drive a probe in the dual-probe mechanism to move to a position of a detection point of a material. When the probe contacts the detection point, the detection mechanism collects measurement data of the detection point. Determining whether the material is an unqualified material according to the measurement data and preset standard information. When the material is the unqualified material, abnormal data is obtained from the measurement data. The present disclosure reduces human errors, improves data accuracy and reliability, and significantly improves work efficiency.

### TECHNICAL FIELD

The present disclosure relates to a field of detection technology, and in particular to an automatic test method, an automatic test device, and a storage medium.

### BACKGROUND

In the field of manufacturing digital electronic products, especially in a production and a quality control of printed circuit board assemblies (PCBAs), it is crucial to test electrical signals of the PCBA to ensure a normal function and a stable performance of the PCBA.

However, PCBA's electrical signals are of various types and are easily affected by various factors such as power supply fluctuations and interference noise. At present, in a process of measuring electrical signals, in order to ensure an accuracy of a measurement, a staff needs to use high-precision measuring instruments and follow strict testing procedures. These measuring instruments are usually expensive and complicated to operate, which place a high demand on a skill level of the staff. In addition, different staff may have subjective differences in measurement methods and data processing of electrical signals, which affects test results. Therefore, in the existing electrical signal measurement process, whether it is a control of the measuring instrument, a reading of data, or an analysis and a recording of test information, the processes are completed manually, resulting the measurement processes being cumbersome, and a measurement efficiency is low, and the accuracy and reliability of a test result is low.

### BRIEF DESCRIPTION OF THE DRAWINGS

FIG. 1 is a schematic diagram of a flowchart of an automatic test method provided in an embodiment of the present disclosure.

FIG. 2 is a schematic diagram of a structure of an automatic test device provided in an embodiment of the present disclosure.

FIG. 3 is a schematic diagram of a flowchart of an automatic test method provided in another embodiment of the present disclosure.

FIG. 4 is a schematic diagram of a structure of an automatic test apparatus provided in an embodiment of the present disclosure.

FIG. 5 is a schematic diagram of a hardware structure of an automatic test device provided in another embodiment of the present disclosure.

### DETAILED DESCRIPTION

The embodiments of the present disclosure are described in detail below, and examples of the embodiments are shown in the accompanying drawings, where the same or similar reference numerals throughout represent the same or similar components or components with the same or similar functions. The embodiments described below with reference to the accompanying drawings are exemplary and are only used to explain the present disclosure, and cannot be understood as limiting the present disclosure.

In the embodiments of the present disclosure, it should be noted that, unless otherwise clearly specified and limited, words such as “for example” are used to indicate examples, illustrations or explanations. Any embodiment or design described as “for example” in the embodiments of the present disclosure should not be interpreted as being more preferred or more advantageous than other embodiments or designs. Specifically, the use of words such as “for example” is intended to present related concepts in a specific way.

In the description of the present disclosure, it should be noted that, unless otherwise clearly specified and limited, the terms “installed”, “connected”, and “connection” should be understood in a broad sense, for example, it may be a fixed connection, a detachable connection, or an integral connection; it may be a mechanical connection, an electrical connection, or may communicate with each other; it may be a direct connection, or it may be indirectly connected through an intermediary medium, it may be an internal connection of two components or an interaction relationship between two components. For the skilled in the art, specific meanings of the above terms in the present disclosure may be understood according to specific circumstances.

In the description of the present disclosure, it should be noted that, unless otherwise expressly specified and limited, the terms “first” and “second” are used for descriptive purposes only and cannot be understood as indicating or implying relative importance or implicitly indicating the number of technical features indicated. Therefore, the features defined as “first” and “second” may explicitly or implicitly include one or more of the features. In addition, in the description of the present disclosure, the meaning of “a plurality of” is two or more, unless otherwise clearly and specifically limited.

In order to more clearly understand the above-mentioned purpose, features and advantages of the present disclosure, the present disclosure is described in detail below in conjunction with the accompanying drawings and specific embodiments. It should be noted that the embodiments of the present disclosure and the features in the embodiments may be combined with each other without conflict.

PCBA's electrical signals are of various types and are easily affected by various factors such as power supply fluctuations and interference noise. At present, in a process of measuring electrical signals, in order to ensure the accuracy of a measurement, a staff needs to use high-precision measuring instruments and follow strict testing procedures. These measuring instruments are often expensive and complicated to operate, which place a high demand on a skill level of the staff. In addition, different staff may have subjective differences in measurement methods and data processing of electrical signals, which affects test results. Therefore, in the existing electrical signal measurement process, whether it is a control of the measuring instrument, a reading of data, or an analysis and a recording of test information, it needs to be completed manually, resulting the measurement processes being cumbersome, and a measurement efficiency is low, and an accuracy and a reliability of a test result is weak.

In view of the above, the present disclosure provides an automatic test method, an automatic test device, an automatic test apparatus, and a storage medium to solve the above-mentioned technical problems.

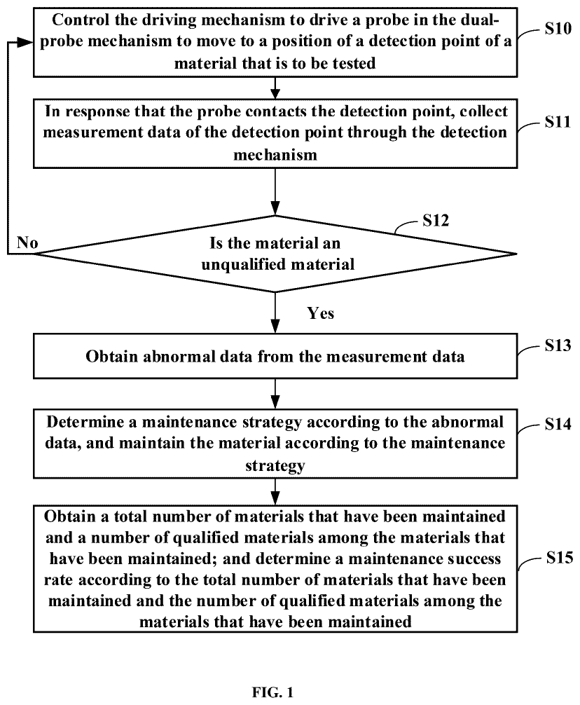

Please refer to FIG. 1, which is a schematic diagram of a flowchart of an automatic test method provided in an embodiment of the present disclosure.

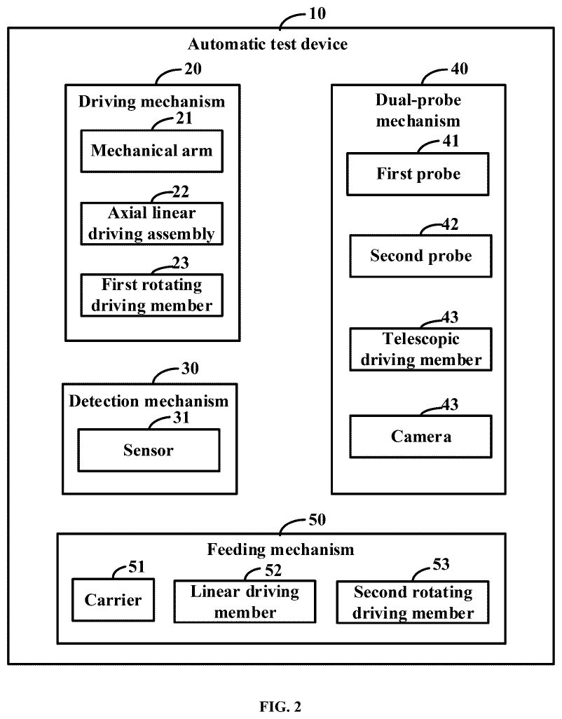

The automatic test method provided in the embodiment of the present disclosure is applied to at least one automatic test device 10 (as shown in FIG. 2). The automatic test device 10 is a device that may automatically perform numerical calculations and/or information processing according to pre-set or stored instructions. Hardware of the automatic test device 10 includes but is not limited to a microprocessor, an application specific integrated circuit (ASIC), a programmable gate array (FPGA), a digital signal processor (DSP), an embedded device, etc.

In other embodiments, the automatic test device 10 may be connected to a desktop computer, a notebook, a PDA, a cloud server, etc. The automatic test device 10 may interact with a user through a keyboard, a mouse, a remote control, a touch pad, or a voice control device.

As shown in FIG. 2, in some embodiments, the automatic test device 10 includes a driving mechanism 20, a detection mechanism 30, a dual-probe mechanism 40 and a feeding mechanism 50. The driving mechanism 20 includes a mechanical arm 21, an axial linear driving assembly 22, and a first rotating driving member 23. The detection mechanism 30 includes a sensor 31, and the sensor 31 is disposed on the mechanical arm 21. The dual-probe mechanism 40 is disposed at an end of the mechanical arm 21 and is connected to the axial linear driving assembly 22 and the first rotating driving member 23. The dual-probe mechanism 40 includes a first probe 41, a second probe 42, a telescopic driving member 43 and a camera 44; the telescopic driving member 43 is connected to the second probe 42, and the camera 44 is arranged in parallel with the first probe 41 and the second probe 42. The feeding mechanism 50 includes a carrier 51, a linear driving member 52 and a second rotating driving member 53. The second rotating driving member 53 is connected to the linear driving member 52. The carrier 51 is disposed on the second rotating driving member 53.

Specifically, an automatic test method includes following blocks. According to different requirements, an order of some blocks in the flowchart may be changed, and some blocks may be omitted.

S10, a driving mechanism is controlled to drive a probe in a dual-probe mechanism to move to a position of a detection point of a material that is to be tested.

In some embodiments, before the driving mechanism 20 drives the probe in the dual-probe mechanism 40 to move to the position of the detection point of the material, the automatic test method further includes: moving the material to a preset detection position through the feeding mechanism 50. Specifically, after the material is placed on the carrier 51, the material is transported by the linear driving member 52, and a placement state of the material (such as a horizontally placed state, a vertically placed state, etc.) is adjusted by the second rotating driving member 53, so as to facilitate a subsequent comprehensive measurement of the material by the dual-probe mechanism 40.

In some embodiments, the automatic test device 10 pre-stores position information of the preset detection point of the material, and the automatic test device 10 determines movement information of the driving mechanism 20 based on the position information of the preset detection point, and controls the driving mechanism 20 to drive the probes in the dual-probe mechanism 40 to move to the position of the detection point of the material. Specifically, the probes in the dual-probe mechanism 40 may be moved to the position of the detection point of the material under a cooperation of the mechanical arm 21, the axial linear drive assembly 22, and the first rotating drive member 23.

S11, when the probe contacts the detection point, measurement data of the detection point is collected by using the detection mechanism.

In some embodiments, the measurement data includes frequency, modulation mode, etc. of an electronic signal.

In some embodiments, when the probe contacts the detection point, the detection mechanism 30 collects the measurement data of the detection point and sends the measurement data to the automatic test device 10, and the automatic test device 10 identifies the received measurement data, determines key parameters such as a range of the frequency and the modulation mode of the electronic signal, and determines whether the electronic signal is a low-frequency/conventional signal or a high-frequency/radio frequency signal based on the key parameters of the electronic signal. When the electronic signal is the low-frequency/conventional signal, the automatic test device 10 generates a first control signal; when the electronic signal is the high-frequency/radio frequency signal, the automatic test device 10 generates a second control signal.

In some embodiments, the automatic test device 10 controls the telescopic drive member 43 based on the first control signal to drive the second probe 42 to move upward, so that an end of the second probe 42 is located above an end of the first probe 41, where the first control signal indicates that the first probe 41 is in contact with the detection point. The first probe 41 is an LCR test flying probe (where in LCR, the L represents an inductance, C represents a capacitor, and the R represents a resistance), which is used to measure the low-frequency or conventional signal. When the first probe 41 contacts the detection point, the automatic test device 10 collects the measurement data of the detection point through the detection mechanism 30, such as an inductance value, a capacitance value, a resistance value, an impedance value, etc.

In some embodiments, the automatic test device 10 controls the telescopic drive member 43 based on the second control signal to drive the second probe 42 to move downward, so that the end of the second probe 42 is located above the end of the first probe 41, where the second control signal indicates that the second probe 42 is in contact with the detection point. The second probe 42 is a high-frequency test flying probe, which is used to measure the high-frequency/radio frequency signal. When the second probe 42 contacts the detection point, the automatic test device 10 collects the measurement data of the detection point through the detection mechanism 30, such as the inductance value, the capacitance value, the resistance value, the impedance value, etc.

The automatic test method of the above embodiment realizes an automatic switching of the first probe 41 and the second probe 42, reduces manual operation of the staff, and reduces an influence of human factors on the measurement data; through the automatic switching of the first probe 41 and the second probe 42, the measurement of the low-frequency/conventional signal and the high-frequency/radio frequency signal may be completed more quickly, shortening a cycle; different probes are selected for different types of signals for measurement, thereby improving an accuracy of the measurement result.

S12, whether the material is an unqualified material is determined according to the measurement data and preset standard information.

In some embodiments, before executing step S12, the automatic test method further pre-obtains the preset standard information. In some embodiments, the preset standard information may be prestored in a storage device of the automatic test device 10.

Specifically, by comparing the measurement data with the preset standard information, when the measurement data meets the preset standard information, the material is determined to be a qualified material; when the measurement data does not meet the preset standard information, the material is determined to be an unqualified material.

In some embodiments, when the material is the unqualified material, step S13 is further processed.

In some embodiments, when the material is the qualified material, the process returns to block S10 to perform a next round of testing.

S13, abnormal data in the measurement data is determined, and the abnormal data is obtained from the measurement data.

In some embodiments, by comparing the measurement data with preset standard information, the measurement data that does not meet the preset standard information is determined as abnormal data.

The automatic test method of the above embodiment may automatically, quickly and accurately detect unqualified materials, thereby improving the yield rate. It may further automatically obtain the abnormal data of unqualified materials and realize automatic analysis of reasons for the unqualified materials to be tested.

In some embodiments, after block S13, the automatic test method further includes following blocks:

S14, a maintenance strategy is determined according to the abnormal data, and the material is maintained according to the maintenance strategy.

In some embodiments, before block S14, the automatic test method further pre-stores the maintenance strategy, and establishes an association relationship between the abnormal data and the maintenance strategy.

Specifically, the automatic test device 10 determines the maintenance strategy for the material based on the abnormal data and the association relationship between the abnormal data and the maintenance strategy, and then performs the maintenance on the material according to the maintenance strategy.

The automatic test method in the above embodiment may quickly determine the maintenance strategy, ensure the orderly progress of a maintenance work, and improve a maintenance efficiency; further predicting the maintenance strategy may timely discover potential problems, avoid an expansion of unqualified products, avoid unnecessary repairs and replacements, reduce maintenance costs, and ensure production safety and stability.

S15, a total number of materials that have been maintained and a number of qualified materials among the materials that have been maintained are obtained, and a maintenance success rate is determined according to the total number of materials that have been maintained and the number of qualified materials among the materials that have been maintained.

The automatic test method in the above embodiment may reduce human errors, improve the data accuracy and the reliability, and significantly improve work efficiency by automatically obtaining the total number of materials that have been maintained and the number of qualified materials among the materials that have been maintained. The maintenance success rate may further be accurately calculated. The maintenance success rate is an important indicator for measuring maintenance quality and service level, which helps to discover potential problems and bottlenecks in the maintenance process. It is of great significance for evaluating the work performance of the maintenance department, optimizing the maintenance process, and reducing maintenance costs.

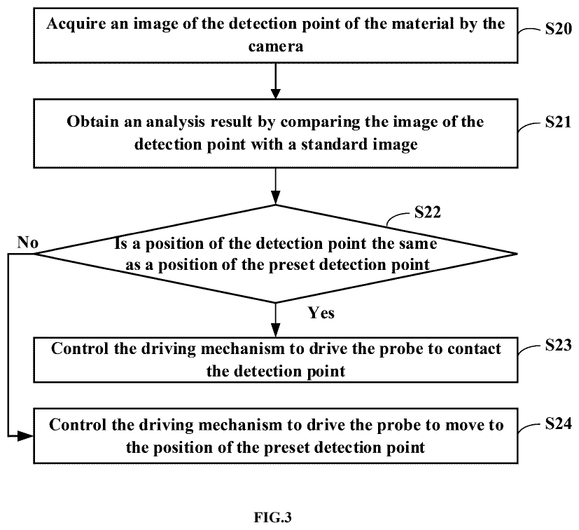

As shown in FIG. 3, in some embodiments, before block S11, the automatic test method further includes the following blocks:

S20, an image of the detection point of the material that is to be tested is obtained through a camera.

Specifically, the image of the detection point of the material is captured by the camera 44, and then the image of the detection point is fed back to the automatic test device 10.

S21, an analysis result is obtained by comparing the image of the detection point with a standard image.

In some embodiments, the standard image includes a preset detection point.

S22, whether a position of the detection point is the same as a position of the preset detection point is determined according to the analysis result.

In some embodiments, when the position of the detection point is the same as the position of the preset detection point, block S23 is processed.

In some embodiments, when the position of the detection point is different from the position of the preset detection point, block S24 is processed.

S23, the driving mechanism is controlled to drive the probe to contact the detection point.

In some embodiments, when the position of the detection point is the same as the position of the preset detection point, it indicates that the position of the detection point pointed by the probe is correct, and then the driving mechanism 20 may be controlled to drive the probe to contact the detection point.

Specifically, the probe in the dual-probe mechanism 40 may be moved to the position of the detection point of the material by the mechanical arm 21.

S24, the driving mechanism is controlled to drive the probe to move to a position of the preset detection point.

In some embodiments, when the position of the detection point is different from the position of the preset detection point, it indicates that the position of the detection point pointed to by the probe is incorrect, and the driving mechanism 20 may be controlled to drive the probe to move to the position of the preset detection point.

Specifically, the probe may be driven to move to the position of the preset detection point by the axial linear drive assembly 22.

In the above embodiment, the accuracy of the automatic test is improved by automatically confirming the position of the detection point, and an occurrence of measurement accidents may be avoided.

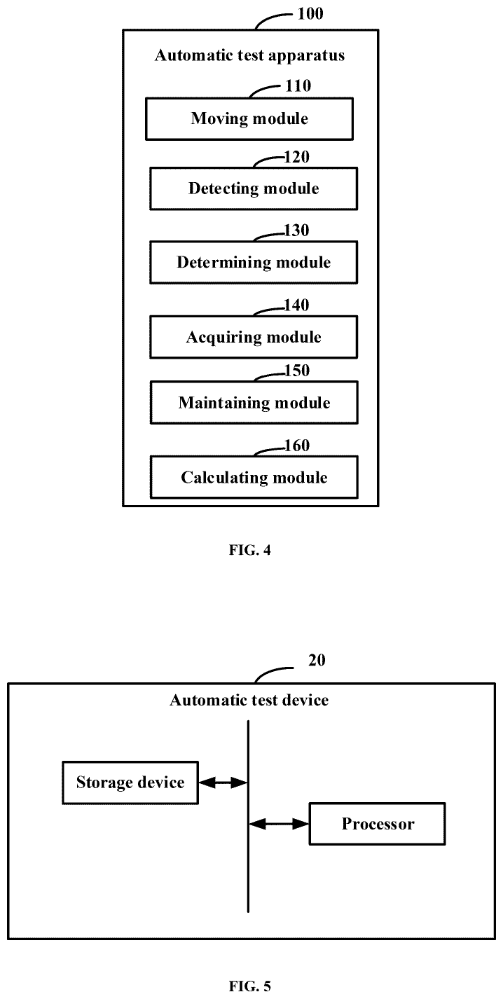

FIG. 4 is a structure diagram of an automatic test apparatus 100 provided in accordance with an embodiment of the present disclosure.

In this embodiment, based on the same concept as the automatic test method in the above embodiment, the present disclosure also provides the automatic test apparatus 100, which may be used to perform the above automatic test method. For ease of explanation, the structure diagram of the embodiment of the automatic test apparatus 100 only shows parts related to the embodiment of the present disclosure. It may be understood by those skilled in the art that the illustrated structure does not constitute a limitation on the automatic test apparatus 100, and it may include more or less components than shown in the figure, or combine certain components, or arrange components differently.

Specifically, the automatic test apparatus 100 provided in the embodiment of the present disclosure includes a moving module 110, a detecting module 120, a determining module 130, and an acquiring module 140.

The moving module 110 is used to control the driving mechanism 20 to drive the probe in the dual-probe mechanism 40 to move to the position of the detection point of the material that is to be tested.

In some embodiments, before the moving module 110 controls the driving mechanism 20 to drive the probe in the dual-probe mechanism 40 to move to the position of the detection point of the material, the material needs to be moved to the preset detection position by the feeding mechanism 50. Specifically, after the material is placed on the carrier 51, the material is transported by the linear driving member 52, and the placement state of the material (such as the horizontally placed state, the vertically placed state, etc.) is adjusted by the second rotating driving member 53, so as to facilitate the subsequent comprehensive measurement of the material by the dual-probe mechanism 40.

In some embodiments, the moving module 110 pre-stores the position information of the preset detection point of the material, and the moving module 110 determines the movement information of the driving mechanism 20 based on the position information of the preset detection point, and controls the driving mechanism 20 to drive the probe in the dual-probe mechanism 40 to move to the position of the detection point of the material. Specifically, the probe in the dual-probe mechanism 40 may be moved to the position of the detection point of the material by the cooperation of the mechanical arm 21, the axial linear drive assembly 22, and the first rotating drive member 23.

The detection module 120 is used to collect measurement data of the detection point through the detection mechanism 30 when the probe contacts the detection point.

In some embodiments, the measurement data includes the frequency, the modulation mode, etc. of the electronic signal.

In some embodiments, when the probe contacts the detection point, the detection module 120 collects the measurement data of the detection point through the detection mechanism 30, identifies the measurement data, determines the key parameters such as the range of the frequency and the modulation mode of the electronic signal, and determines whether the electronic signal is the low-frequency/conventional signal or the high-frequency/radio frequency signal based on the key parameters of the electronic signal. When the electronic signal is the low-frequency/conventional signal, the detection module 120 generates the first control signal; when the electronic signal is the high-frequency/radio frequency signal, the detection module 120 generates the second control signal.

In some embodiments, the moving module 110 controls the telescopic drive member 43 based on the first control signal to drive the second probe 42 to move upward, so that the end of the second probe 42 is located above the end of the first probe 41, where the first control signal indicates that the first probe 41 is in contact with the detection point. The first probe 41 is the LCR test flying probe (where in LCR, the L represents the inductance, C represents the capacitor, and the R represents the resistance), which is used to measure the low-frequency or conventional signal. When the first probe 41 contacts the detection point, the detection module 120 collects the measurement data of the detection point through the detection mechanism 30, such as the inductance value, the capacitance value, the resistance value, the impedance value, etc.

In some embodiments, the moving module 110 controls the telescopic drive member 43 based on the second control signal to drive the second probe 42 to move downward, so that the end of the second probe 42 is located above the end of the first probe 41, where the second control signal indicates that the second probe 42 is in contact with the detection point. The second probe 42 is the high-frequency test flying probe, which is used to measure the high-frequency or radio frequency signal. When the second probe 42 contacts the detection point, the detection module 120 collects the measurement data of the detection point through the detection mechanism 30, such as the inductance value, the capacitance value, the resistance value, the impedance value, etc.

The automatic test method of the above embodiment realizes the automatic switching of the first probe 41 and the second probe 42, reduces manual operation of the staff, and reduces the influence of human factors on the measurement data; through the automatic switching of the first probe 41 and the second probe 42, the measurement of low-frequency or conventional signals and high-frequency or radio frequency signals may be completed more quickly, shortening the cycle; different probes are selected for different types of signals for measurement, thereby improving accuracy of the measurement results.

The determining module 130 is used to determine whether the material is the unqualified material according to the measurement data and the preset standard information.

In some embodiments, before determining whether the material is the unqualified material based on the measurement data and the preset standard information, the determining module 130 pre-obtains the preset standard information.

Specifically, by comparing the measurement data with the preset standard information, when the measurement data meets the preset standard information, the determining module 130 may determine that the material is a qualified material; when the measurement data does not meet the preset standard information, the determining module 130 may determine that the material is an unqualified material.

The acquisition module 140 is used to determine abnormal data from the measurement data when the material is unqualified

In some embodiments, by comparing the measurement data with preset standard information, the measurement data that does not meet the preset standard information is determined as abnormal data.

The automatic test method of the above embodiment may automatically, quickly and accurately detect unqualified materials, thereby improving the yield rate. It may further automatically obtain abnormal data of unqualified materials and realize automatic analysis of the reasons for the unqualified materials to be tested.

In some embodiments, the automatic test apparatus 100 further includes a maintaining module 150 and a calculating module 160.

The maintaining module 150 is used to determine a maintenance strategy according to the abnormal data, and to maintain the material according to the maintenance strategy.

In some embodiments, the maintaining module 150 pre-stores the maintenance strategy and establishes the association relationship between the abnormal data and the maintenance strategy.

Specifically, the maintaining module 150 determines the maintenance strategy of the material based on the abnormal data and the association between the abnormal data and the maintenance strategy, and then performs maintenance on the material according to the maintenance strategy.

The automatic test method in the above embodiment may quickly determine the maintenance strategy, ensure the orderly progress of maintenance work, and improve maintenance efficiency; further predicting the maintenance strategy may timely discover potential problems, avoid the expansion of unqualified products, avoid unnecessary repairs and replacements, reduce maintenance costs, and ensure production safety and stability.

The calculating module 160 is used to obtain the total number of materials that have been maintained and the number of qualified materials among the materials that have been maintained, and to determine the maintenance success rate according to the total number of materials that have been maintained and the number of qualified materials among the materials that have been maintained.

The automatic test apparatus 100 in the above embodiment may reduce human errors, improve data accuracy and reliability, and significantly improve work efficiency by automatically obtaining the total number of materials that have been maintained and the number of qualified materials among the materials that have been maintained. The maintenance success rate may further be accurately calculated. The maintenance success rate is an important indicator for measuring the maintenance quality and the service level, which helps to discover potential problems and bottlenecks in the maintenance process. It is of great significance for evaluating the work performance of the maintenance department, optimizing the maintenance process, and reducing maintenance costs.

FIG. 5 is a schematic diagram of a hardware structure of an automatic test device 10 provided in an embodiment of the present disclosure.

In some embodiments, the automatic test device 10 includes, but is not limited to, a storage device 11, a processor 12, and a computer program (such as an automatic test program) stored in the storage device 11 and executable on the processor 12. In some embodiments, the automatic test device 10 shown in FIG. 5 may be regarded as one embodiment of the automatic test device 10, which includes the components shown in FIG. 5 in addition to the components shown in FIG. 2.

Those skilled in the art may appreciate that the schematic diagram is merely an example of the automatic test device 10 and does not constitute a limitation on the automatic test device 10. The automatic test device 10 may include more or fewer components than shown in the diagram, or a combination of certain components, or different components. For example, the automatic test device 10 may also include input and output devices, network access devices, buses, etc.

The processor 12 obtains the operating system and various installed application programs of the automatic test device 10. The processor 12 obtains the application program to implement the blocks in the above-mentioned various embodiments of the automatic test method, such as the blocks shown in FIG. 1 and FIG. 3.

Exemplarily, the computer program may be divided into one or more modules/units, one or more modules/units are stored in the storage device 11, and are obtained by the processor 12 to complete the present disclosure. One or more modules/units may be a series of computer program instruction segments capable of completing specific functions, and the instruction segments are used to describe the acquisition process of the computer program in the automatic test device 10.

In some embodiments, the automatic test device 10 includes that may automatically perform numerical calculations and/or information processing according to pre-set or stored instructions. The hardware of the automatic test device 10 includes, but is not limited to, a microprocessor, an application specific integrated circuit (ASIC), a field-programmable gate array (FPGA), a digital signal processor (DSP), an embedded device, etc.

In some embodiments, the network where the automatic test device 10 is located includes, but is not limited to: the Internet, a wide area network, a metropolitan area network, a local area network, a virtual private network (VPN), etc.

In some embodiments, the storage device 11 is used to store program codes and various data, such as the automatic test apparatus 100 installed in the automatic test device 10, and to achieve high-speed and automatic access to programs or data during the operation of the automatic test device 10. The storage device 11 may include a read-only memory (ROM), a random access memory (RAM), a programmable read-only memory (PROM), an erasable programmable read-only memory (EPROM), a one-time programmable read-only memory (OTPROM), an electronically erasable rewritable read-only memory (EEPROM), a compact disc read-only memory (CD-ROM) or other optical disc storage, magnetic disk storage, magnetic tape storage, or any other computer-readable medium that may be used to carry or store data.

In some embodiments, the storage device 11 may also be an external storage device and/or an internal storage device of the automatic test device 10. Furthermore, the storage device 11 may be a storage device in a physical form, such as a memory stick, a TF card (Trans-flash Card), and the like.

In some embodiments, the processor 12 may be a central processing unit (CPU), or other general-purpose processors, digital signal processors (DSP), application-specific integrated circuits (ASIC), field-programmable gate arrays (FPGA) or other programmable logic devices, discrete gate or transistor logic devices, discrete hardware components, etc. The general-purpose processor may be a microprocessor or any conventional processor, etc. The processor 12 is a computing core and a control center of the automatic test device 10, and uses various interfaces and lines to connect various parts of the entire automatic test device 10, and invokes data stored in the storage device 11 to execute various functions of the automatic test device 10 and process data, such as executing the test function of the automatic test device 10.

In some embodiments, the processor 12 is used to obtain the operating system and various installed applications of the automatic test device 10. For example, the processor 12 obtains the automatic test program to implement the automatic test using the automatic test method of the above embodiment, such as the blocks shown in FIG. 1 and FIG. 3.

In one embodiment of the present disclosure, the automatic test device 10 may also include a power supply (not shown) for supplying power to each component. Preferably, the power supply may be logically connected to the processor 12 through a power management device, so that the power management device may manage charging, discharging, and power consumption management. The power supply may also include one or more DC or AC power supplies, recharging devices, power failure detection circuits, power converters or inverters, power status indicators, and other arbitrary components. The automatic test device 10 may also include a BLUETOOTH module, a Wi-Fi module, etc., which will not be repeated here.

In one embodiment of the present disclosure, if the module/submodule integrated in the automatic test device 10 is implemented in the form of a software functional submodule and sold or used as an independent workpiece, it may be stored in a computer-readable storage medium. Based on this understanding, the present disclosure implements all or part of the process in the above-mentioned embodiment method, and may also be completed by instructing the relevant hardware through a computer program. The computer program may be stored in a computer-readable storage medium. When the computer program is obtained by the processor 12, the steps of each method embodiment shown in FIG. 1 and FIG. 3 may be implemented.

In one embodiment of the present disclosure, the computer program may include computer program code, which may be in a form of source code, in a form of object code, in a form of an executable file, or in an intermediate form, etc. The computer readable storage medium may include: any entity or device, recording medium, USB flash drive, mobile hard disk, magnetic disk, optical disk, computer storage device, and read-only memory (ROM) that are capable of carrying computer program code.

The storage device 11 in the automatic test device 10 stores a plurality of instructions to implement the automatic test method, and the processor 12 may obtain and execute the plurality of instructions to implement the automatic test method of the above embodiment.

Specifically, the specific implementation method of the processor 12 for the above instructions may refer to the description of the relevant blocks in the corresponding embodiments of FIG. 1 and FIG. 3, which will not be repeated here.

In the several embodiments provided in the present disclosure, it should be understood that the disclosed methods and devices may be implemented in other ways. For example, the device embodiments described above are only schematic, for example, the division of modules is only a logical function division, and there may be other division methods in actual implementation.

The modules described as separate components may or may not be physically separated, and the components shown as modules may or may not be physical units, that is, they may be located in one place or distributed on multiple network units. Some or all of the modules may be selected according to actual needs to achieve the purpose of the solution of this embodiment.

Each functional module in each embodiment of the present disclosure may be integrated into a processing submodule, or each submodule may exist physically separately, or two or more submodules may be integrated into one submodule. The above-mentioned integrated submodule may be implemented in the form of hardware or in the form of hardware plus software functional modules.

Therefore, no matter from which point of view, the embodiments should be regarded as illustrative and non-restrictive, and the scope of the present disclosure is limited by the appended claims rather than the above description, so it is intended that all changes falling within the meaning and scope of the equivalent elements of the claims are included in the present disclosure. Any attached figure mark in the claims should not be regarded as limiting the claims involved.

In addition, it is obvious that the word “comprising” does not exclude other submodules or steps, and the singular does not exclude the plural. The multiple submodules or devices stated in the present disclosure may also be implemented by one submodule or device through software or hardware.

Finally, it should be noted that the above embodiments are only used to illustrate the technical solution of the present disclosure and are not intended to limit it. Although the present disclosure has been described in detail with reference to the preferred embodiments, a person of ordinary skill in the art should understand that the technical solution of the present disclosure may be modified or replaced by equivalents without departing from the spirit and scope of the technical solution of the present disclosure.

What is claimed is:

1. An automatic test method applied to an automatic test device, which comprises a driving mechanism, a detection mechanism and a dual-probe mechanism, the automatic test method comprising:
controlling the driving mechanism to drive a probe in the dual-probe mechanism to move to a position of a detection point of a material that is to be tested;
in response to the probe contacting the detection point, collecting measurement data of the detection point through the detection mechanism;
determining whether the material is an unqualified material according to the measurement data and preset standard information; and
in response to the material being determined to be the unqualified material, obtaining abnormal data from the measurement data.

2. The automatic test method according to claim 1, wherein after obtaining the abnormal data from the measurement data, the automatic test method further comprises:
determining a maintenance strategy according to the abnormal data, and maintaining the material according to the maintenance strategy.

3. The automatic test method according to claim 2, wherein after maintaining the material, the automatic test method further comprises:
obtaining a total number of materials that have been maintained and a number of qualified materials among the materials that have been maintained; and
determining a maintenance success rate according to the total number of materials that have been maintained and the number of qualified materials among the materials that have been maintained.

4. The automatic test method according to claim 1, wherein the dual-probe mechanism comprises a camera, and before the probe contacts the detection point, the automatic test method further comprises:
acquiring an image of the detection point of the material by using the camera;
obtaining an analysis result by comparing the image of the detection point with a standard image, the standard image comprising a preset detection point;
determining whether a position of the detection point is the same as a position of the preset detection point according to the analysis result; and
in response to the position of the detection point being the same as the position of the preset detection point, controlling the driving mechanism to drive the probe to contact the detection point.

5. The automatic test method according to claim 4, wherein before the probe contacts the detection point, the automatic test method further comprises:
in response to the position of the detection point being different from the position of the preset detection point, controlling the driving mechanism to drive the probe to move to the position of the preset detection point.

6. The automatic test method according to claim 1, wherein the dual-probe mechanism comprises a first probe, a second probe and a telescopic drive member, and the automatic test method further comprises:
based on a first control signal, driving the second probe to move upward, to enable an end of the second probe to be located above an end of the first probe, by controlling the telescopic drive member, wherein the first control signal indicates that the first probe is in contact with the detection point; and
based on a second control signal, driving the second probe to move downward, to enable the end of the second probe to be located above the end of the first probe, by controlling the telescopic drive member, wherein the second control signal indicates that the second probe is in contact with the detection point.

7. The automatic test method according to claim 1, wherein before controlling the driving mechanism to drive the probe in the dual-probe mechanism to move to the position of the detection point of the material, the automatic test method further comprises:
moving the material to a preset detection position by using a feeding mechanism.

8. An automatic test device, comprising a driving mechanism, a detection mechanism, a dual-probe mechanism, a storage device, and a processor, an automatic testing program being stored in the storage device, which when executed by the processor, causing the processor to:
control the driving mechanism to drive a probe in the dual-probe mechanism to move to a position of a detection point of a material that is to be tested;
in response to the probe contacting the detection point, collect measurement data of the detection point through the detection mechanism;
determine whether the material is an unqualified material according to the measurement data and preset standard information; and
in response to the material being determined to be the unqualified material, obtain abnormal data from the measurement data.

9. The automatic test device according to claim 8, wherein after obtaining the abnormal data from the measurement data, the processor is further caused to:
determine a maintenance strategy according to the abnormal data, and maintain the material according to the maintenance strategy.

10. The automatic test device according to claim 9, wherein after maintaining the material, the processor is further caused to:
obtain a total number of materials that have been maintained and a number of qualified materials among the materials that have been maintained; and
determine a maintenance success rate according to the total number of materials that have been maintained and the number of qualified materials among the materials that have been maintained.

11. The automatic test device according to claim 8, wherein the dual-probe mechanism comprises a camera, and before the probe contacts the detection point, the processor is further caused to:
acquire an image of the detection point of the material by using the camera;
obtain an analysis result by comparing the image of the detection point with a standard image, the standard image comprising a preset detection point;
determine whether a position of the detection point is the same as a position of the preset detection point according to the analysis result; and
in response to the position of the detection point being the same as the position of the preset detection point, control the driving mechanism to drive the probe to contact the detection point.

12. The automatic test device according to claim 11, wherein before the probe contacts the detection point, the processor is further caused to:
in response to the position of the detection point being different from the position of the preset detection point, control the driving mechanism to drive the probe to move to the position of the preset detection point.

13. The automatic test device according to claim 8, wherein the dual-probe mechanism comprises a first probe, a second probe and a telescopic drive member, and the processor is further caused to:
based on a first control signal, drive the second probe to move upward, to enable an end of the second probe to be located above an end of the first probe, by controlling the telescopic drive member, wherein the first control signal indicates that the first probe is in contact with the detection point; and
based on a second control signal, drive the second probe to move downward, to enable the end of the second probe to be located above the end of the first probe, by controlling the telescopic drive member, wherein the second control signal indicates that the second probe is in contact with the detection point.

14. The automatic test device according to claim 8, wherein before controlling the driving mechanism to drive the probe in the dual-probe mechanism to move to the position of the detection point of the material, the processor is further caused to:
move the material to a preset detection position by using a feeding mechanism.

15. A non-transitory storage medium, being stored with an automatic testing program, which when executed by a processor, causing the processor to perform an automatic test method, wherein the automatic test method comprises:
controlling the driving mechanism to drive a probe in the dual-probe mechanism to move to a position of a detection point of a material that is to be tested;
in response to the probe contacting the detection point, collecting measurement data of the detection point through the detection mechanism;
determining whether the material is an unqualified material according to the measurement data and preset standard information; and
in response to the material being determined to be the unqualified material, obtaining abnormal data from the measurement data.

16. The non-transitory storage medium according to claim 15, wherein after obtaining the abnormal data from the measurement data, the automatic test method further comprises:
determining a maintenance strategy according to the abnormal data, and maintaining the material according to the maintenance strategy.

17. The non-transitory storage medium according to claim 16, wherein after maintaining the material, the automatic test method further comprises:
obtaining a total number of materials that have been maintained and a number of qualified materials among the materials that have been maintained; and
determining a maintenance success rate according to the total number of materials that have been maintained and the number of qualified materials among the materials that have been maintained.

18. The non-transitory storage medium according to claim 15, wherein the dual-probe mechanism comprises a camera, and before the probe contacts the detection point, the automatic test method further comprises:
acquiring an image of the detection point of the material by using the camera;
obtaining an analysis result by comparing the image of the detection point with a standard image, the standard image comprising a preset detection point;
determining whether a position of the detection point is the same as a position of the preset detection point according to the analysis result; and
in response to the position of the detection point being the same as the position of the preset detection point, controlling the driving mechanism to drive the probe to contact the detection point.

19. The non-transitory storage medium according to claim 18, wherein before the probe contacts the detection point, the automatic test method further comprises:
in response to the position of the detection point being different from the position of the preset detection point, controlling the driving mechanism to drive the probe to move to the position of the preset detection point.

20. The non-transitory storage medium according to claim 15, wherein the dual-probe mechanism comprises a first probe, a second probe and a telescopic drive member, and the automatic test method further comprises:
based on a first control signal, driving the second probe to move upward, to enable an end of the second probe to be located above an end of the first probe, by controlling the telescopic drive member, wherein the first control signal indicates that the first probe is in contact with the detection point; and
based on a second control signal, driving the second probe to move downward, to enable the end of the second probe to be located above the end of the first probe, by controlling the telescopic drive member, wherein the second control signal indicates that the second probe is in contact with the detection point.
